(19) United States
(12) Patent Application Publication
(10) Pub. No.: US 2018/0366605 A1
(43) Pub. Date: Dec. 20, 2018

(54) SOLAR POWER SUNROOF DEVICE HAVING LOW REFLECTANCE AND MANUFACTURING METHOD THEREOF

(71) Applicant: NEXPOWER TECHNOLOGY CORPORATION, Taichung City (TW)

(72) Inventors: Yung-Lin CHEN, Taichung City (TW); Jia-Ming LEE, Taichung City (TW); Chia-Ling LEE, Taichung City (TW); Cheng-Yi CHOU, Taichung City (TW)

(21) Appl. No.: 16/006,891

(22) Filed: Jun. 13, 2018

(30) Foreign Application Priority Data
Jun. 16, 2017 (TW) 106120240

(51) Int. Cl. H01L 31/056; B60L 8/00; H01L 31/0468; H01L 31/0224; H01L 31/05; H01L 31/18

(52) U.S. Cl. CPC H01L 31/056; B60L 8/003; H01L 31/18; H01L 31/022466; H01L 31/0516; H01L 31/0468

(57) ABSTRACT

A solar power sunroof device having a low reflectance is for receiving and reflecting a solar ray and a visible ray. A substrate is illuminated by the solar ray. A front contact layer has a first upper connecting surface and a first lower connecting surface. The first upper connecting surface is connected to the substrate. A photoelectric conversion layer is connected between the first lower connecting surface and a back contact layer. A low reflective layer has a third upper connecting surface and a third lower connecting surface. The third upper connecting surface is connected to the back contact layer, and the third lower connecting surface has a visible light reflectance. The visible ray illuminates the third lower connecting surface of the low reflective layer, and the third lower connecting surface scatters or absorbs the visible ray so as to decrease the visible light reflectance.

### RELATED APPLICATIONS

This application claims priority to Taiwan Application Serial Number 106120240, filed Jun. 16, 2017, which is herein incorporated by reference.

### BACKGROUND

### Technical Field

The present disclosure relates to a solar power sunroof device and a manufacturing method thereof. More particularly, a solar power sunroof device having a low reflectance and a manufacturing method thereof.

### Description of Related Art

In general, a solar power sunroof device has a multi-layer structure which includes a substrate, a front contact layer, a photoelectric conversion layer, a back contact layer and a glass layer. The substrate, the front contact layer, the photoelectric conversion layer, the back contact layer and the glass layer are sequentially stacked with each other. The solar power sunroof device can be used for energy generation, have a certain degree of transparency and increase the field of view.

There is one conventional solar power sunroof device which includes a front substrate, a front contact layer, a photoelectric conversion layer and a back contact layer. The front substrate and the front contact layer are both made of transparent materials. The photoelectric conversion layer absorbs a solar ray from the front substrate. The back contact layer includes an optical layer opposite to the front substrate for scattering a specific ray opposite to the solar ray. The conventional solar power sunroof device may reduce the solar ray from the outside of the vehicle. However, the conventional solar power sunroof device easily produces mirror image and reflection phenomena from the view of people inside the vehicle, thereby decreasing eye comfort. Therefore, a solar power sunroof device having a low reflectance and a manufacturing method thereof having the features of significantly reducing reflection of the visible ray are commercially desirable.

### SUMMARY

According to one aspect of the present disclosure, a solar power sunroof device having a low reflectance is for receiving and reflecting a solar ray and a visible ray. The solar power sunroof device having the low reflectance includes a substrate, a front contact layer, a photoelectric conversion layer, a back contact layer and a low reflective layer. The substrate is illuminated by the solar ray. The front contact layer has a first upper connecting surface and a first lower connecting surface. The first upper connecting surface is connected to the substrate. The photoelectric conversion layer is connected to the first lower connecting surface. The back contact layer has a second upper connecting surface and a second lower connecting surface. The second upper connecting surface is connected to the photoelectric conversion layer. The low reflective layer has a third upper connecting surface and a third lower connecting surface. The third upper connecting surface is connected to the second lower connecting surface, and the third lower connecting surface has a visible light reflectance. The visible ray illuminates the third lower connecting surface of the low reflective layer, and the third lower connecting surface scatters or absorbs the visible ray so as to decrease the visible light reflectance.

According to another aspect of the present disclosure, a manufacturing method of the solar power sunroof device having the low reflectance provides a multilayer stacking step and a surface changing step. The multilayer stacking step is for sequentially stacking the substrate, the front contact layer, the photoelectric conversion layer, the back contact layer and the low reflective layer. The surface changing step is for performing a processing procedure to change the third lower connecting surface so as to decrease the visible light reflectance of the third lower connecting surface.

### BRIEF DESCRIPTION OF THE DRAWINGS

The present disclosure can be more fully understood by reading the following detailed description of the embodiment, with reference made to the accompanying drawings as follows:

FIG. 1 shows a schematic view of a solar power sunroof device having a low reflectance of the present disclosure which is disposed on a vehicle;

FIG. 2 shows a schematic view of a solar power sunroof device having a low reflectance according to a first embodiment of the present disclosure;

FIG. 3 shows a schematic view of a solar power sunroof device having a low reflectance according to a second embodiment of the present disclosure;

FIG. 4 shows a schematic view of a solar power sunroof device having a low reflectance according to a third embodiment of the present disclosure;

FIG. 5 shows a schematic view of a solar power sunroof device having a low reflectance according to a fourth embodiment of the present disclosure;

FIG. 6A shows a schematic view of the low reflective layer according to a first example of FIG. 5;

FIG. 6B shows a schematic view of the low reflective layer according to a second example of FIG. 5;

FIG. 6C shows a schematic view of the low reflective layer according to a third example of FIG. 5;

FIG. 6D shows a schematic view of the low reflective layer according to a fourth example of FIG. 5;

FIG. 6E shows a schematic view of the low reflective layer according to a fifth example of FIG. 5;

FIG. 7A shows a schematic view of a measurement result of a conventional solar power sunroof device;

FIG. 7B shows a schematic view of a measurement result of the solar power sunroof device having the low reflectance of FIG. 2, wherein the low reflective layer is made of nickel (Ni);

FIG. 7C shows a schematic view of a measurement result of the solar power sunroof device having the low reflectance of FIG. 2, wherein the low reflective layer is made of amorphous silicon (a-Si);

FIG. 8 shows a schematic view of a solar power sunroof device having a low reflectance according to a fifth embodiment of the present disclosure;

FIG. 9 shows a schematic view of a solar power sunroof device having a low reflectance according to a sixth embodiment of the present disclosure;

FIG. 10 shows a schematic view of a solar power sunroof device having a low reflectance according to a seventh embodiment of the present disclosure; and

FIG. 11 shows a flow chart of a manufacturing method of a solar power sunroof device having a low reflectance according to one embodiment of the present disclosure.

### DETAILED DESCRIPTION

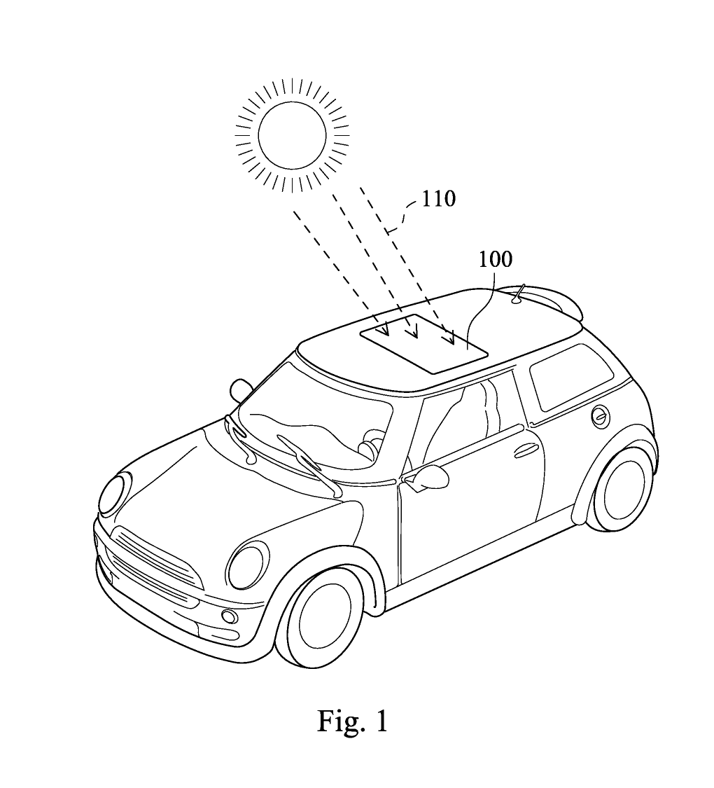

FIG. 1 shows a schematic view of a solar power sunroof device 100 having a low reflectance of the present disclosure which is disposed on a vehicle. The solar power sunroof device 100 having a low reflectance is configured to receive and reflect a solar ray 110 and a visible ray 120. The solar power sunroof device 100 having the low reflectance of the present disclosure is configured to use specific structures to reduce reflection of the visible ray 120 so as to significantly minimize mirror image and reflection phenomena from the view of people inside the vehicle. The solar power sunroof device 100 having the low reflectance can achieve energy generation. Moreover, an external color of the solar power sunroof device 100 having the low reflectance is similar to the vehicle body so as to achieve good visual effects. The solar power sunroof device 100 having the low reflectance can significantly minimize mirror image and reflection phenomena, and the solar ray 110 can smoothly pass through the solar power sunroof device 100 having the low reflectance. The structures can be more fully understood by reading the following detailed description of seven embodiments.

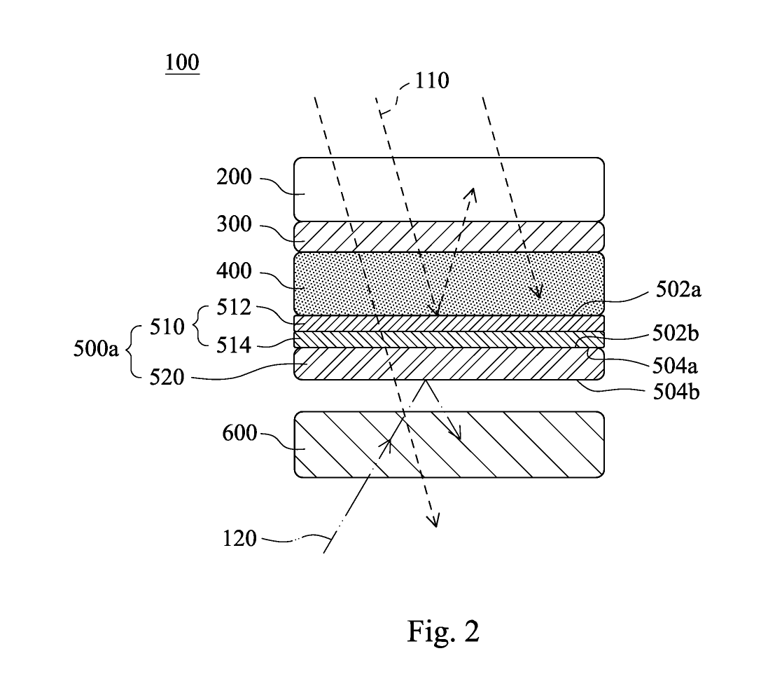

FIG. 2 shows a schematic view of a solar power sunroof device 100 having a low reflectance according to a first embodiment of the present disclosure. In FIGS. 1 and 2, the solar power sunroof device 100 having the low reflectance is configured to utilize a semiconductor material having a high absorption coefficient to reduce the reflectance of a back contact layer 510 made of silver (Ag). The solar power sunroof device 100 having the low reflectance includes a substrate 200, a front contact layer 300, a photoelectric conversion layer 400, a back contact module 500a and a glass layer 600.

The substrate 200 is illuminated by the solar ray 110 and made of a light-transmitting material. The substrate 200 is a photovoltaic substrate (PV substrate) and suitable for use in a solar power device.

The front contact layer 300 has a first upper connecting surface and a first lower connecting surface. The first upper connecting surface is connected to the substrate 200. The front contact layer 300 may be a transparent conductive oxide (TCO) having a single-layer structure or a multi-layer structure. The front contact layer 300 can be made of SnO₂, ITO, ZnO, AZO, GZO or IZO.

The photoelectric conversion layer 400 is connected to the first lower connecting surface of the front contact layer 300 and has a single-layer structure or a multi-layer structure. The photoelectric conversion layer 400 can be made of a crystalline silicon semiconductor material, an amorphous silicon semiconductor material, a semiconductor compound material, an organic semiconductor material or a sensitizing dye material. In addition, the photoelectric conversion layer 400 may be formed by stacking a p-type semiconductor layer, an absorption layer and an n-type semiconductor layer so as to convert sunlight into electricity.

The back contact module 500a includes a back contact layer 510 and a low reflective layer 520. The back contact layer 510 has a second upper connecting surface 502a and a second lower connecting surface 502b. The low reflective layer 520 has a third upper connecting surface 504a and a third lower connecting surface 504b. The second upper connecting surface 502a is connected to the photoelectric conversion layer 400. The second lower connecting surface 502b is connected to the third upper connecting surface 504a of the low reflective layer 520. The third lower connecting surface 504b is located below the low reflective layer 520 and has a visible light reflectance. The back contact layer 510 is made of a metal material, a transparent conductive oxide film or a combination of the metal material and the transparent conductive oxide film. In other words, the back contact layer 510 may be a metal contact layer, a transparent conductive oxide layer or a combination of the metal contact layer and the transparent conductive oxide layer. In one embodiment, the back contact layer 510 includes a transparent conductive oxide layer 512 and a metal contact layer 514. The metal contact layer 514 is made of silver (Ag). The low reflective layer 520 is made of germanium (Ge), nickel (Ni), silicon (Si) or amorphous silicon (a-Si). The visible light reflectance of the third lower connecting surface 504b is less than 50%. The low reflective layer 520 may be an amorphous or polycrystalline continuous film and made of the semiconductor material having the high absorption coefficient, thereby effectively absorbing the visible ray 120. Moreover, the low reflective layer 520 has a first color. The vehicle body includes an interior decorative element having a second color, and the first color of the low reflective layer 520 is corresponding to the second color of the interior decorative element of the vehicle body, so that a vehicle interior of the vehicle body has a uniform color for achieving good visual effects.

The glass layer 600 is connected to the third lower connecting surface 504b of the back contact module 500a and receives the visible ray 120. The visible ray 120 passes through the glass layer 600 which is transparent, and then the visible ray 120 illuminates the third lower connecting surface 504b of the low reflective layer 520. The third lower connecting surface 504b scatters or absorbs the visible ray 120 so as to decrease the visible light reflectance. Therefore, the solar power sunroof device 100 having the low reflectance of the present disclosure can reduce reflection of the visible ray 120 via the semiconductor material having the high absorption coefficient, thus significantly minimizing mirror image and reflection phenomena to increase eye comfort.

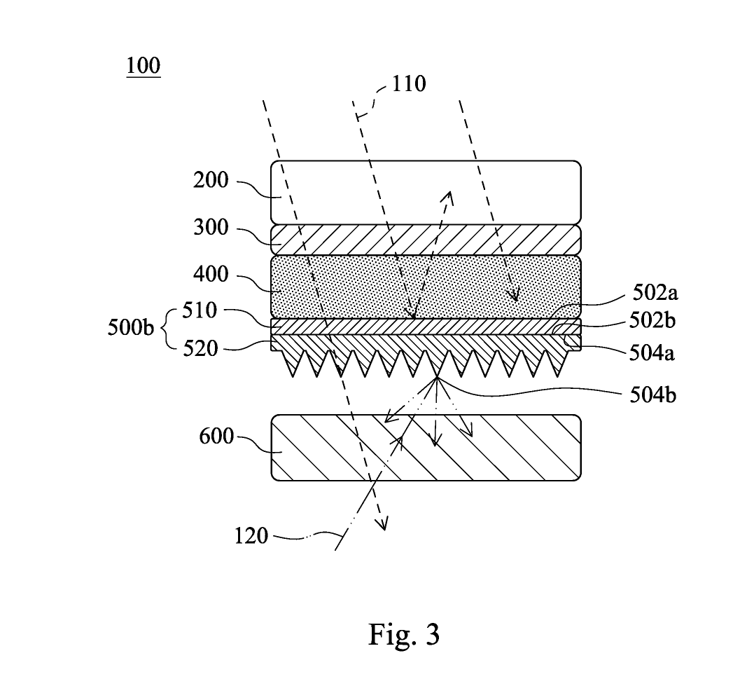

FIG. 3 shows a schematic view of a solar power sunroof device 100 having a low reflectance according to a second embodiment of the present disclosure. In FIGS. 1 and 3, the solar power sunroof device 100 having the low reflectance is configured to utilize an etching process to increase the surface roughness of a low reflective layer 520 made of silver so as to reduce the reflectance of a back contact layer 510. The solar power sunroof device 100 having the low reflectance includes a substrate 200, a front contact layer 300, a photoelectric conversion layer 400, a back contact module 500b and a glass layer 600.

In FIG. 3, the detail of the substrate 200, the front contact layer 300, the photoelectric conversion layer 400 and the glass layer 600 is the same as the first embodiment of FIG. 2 and will not be described again herein. In FIG. 3, the solar power sunroof device 100 having the low reflectance further includes the back contact module 500b. The back contact module 500b includes the back contact layer 510 and the low reflective layer 520. There are three types of material combinations. First, the back contact layer 510 and the low reflective layer 520 are both made of metal materials. Second, the back contact layer 510 and the low reflective layer 520 are both made of transparent conductive oxide films. Third, the back contact layer 510 is made of the transparent conductive oxide film, and the low reflective layer 520 is made of the metal material. In FIG. 3, the material combination belongs to the third type. The metal material of the low reflective layer 520 is silver. The third lower connecting surface 504b of the low reflective layer 520 is etched to form a non-planar shape via the etching process. In detail, the low reflective layer 520 has the third lower connecting surface 504b located below the low reflective layer 520 after the etching process. The third lower connecting surface 504b has a concave-convex shape or a sawtooth shape. The third lower connecting surface 504b has a surface roughness which is greater than or equal to 50 nm, and the visible light reflectance of the third lower connecting surface 504b is less than 50%. Therefore, the solar power sunroof device 100 having the low reflectance of the present disclosure can reduce reflection of the visible ray 120 via the non-planar shape of the third lower connecting surface 504b, thus significantly minimizing mirror image and reflection phenomena to increase eye comfort.

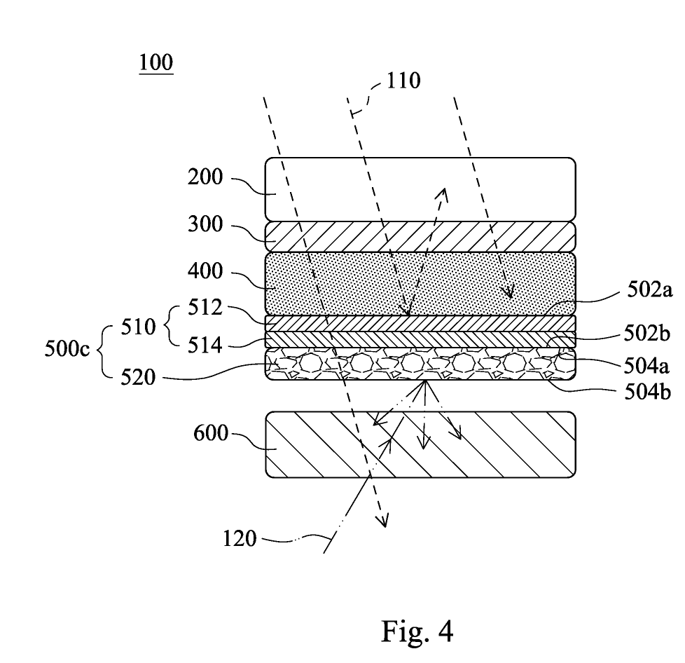

FIG. 4 shows a schematic view of a solar power sunroof device 100 having a low reflectance according to a third embodiment of the present disclosure. In FIGS. 1 and 4, the solar power sunroof device 100 having the low reflectance is configured to utilize a low reflective layer 520 having a high absorption coefficient to reduce the reflectance of a back contact layer 510 made of silver. The solar power sunroof device 100 having the low reflectance includes a substrate 200, a front contact layer 300, a photoelectric conversion layer 400, a back contact module 500c and a glass layer 600.

In FIG. 4, the detail of the substrate 200, the front contact layer 300, the photoelectric conversion layer 400 and the glass layer 600 is the same as the first embodiment of FIG. 2 and will not be described again herein. In FIG. 4, the solar power sunroof device 100 having the low reflectance further includes the back contact module 500c. The back contact module 500c includes the back contact layer 510 and the low reflective layer 520. The back contact layer 510 includes a transparent conductive oxide layer 512 and a metal contact layer 514. The back contact layer 510 has a second upper connecting surface 502a and a second lower connecting surface 502b. The second upper connecting surface 502a is located above the transparent conductive oxide layer 512. The second lower connecting surface 502b is located below the metal contact layer 514. The back contact layer 510 is connected to the low reflective layer 520. The low reflective layer 520 has a third upper connecting surface 504a and a third lower connecting surface 504b. The third upper connecting surface 504a is connected to the second lower connecting surface 502b. The third lower connecting surface 504b has a visible light reflectance. In other words, the low reflective layer 520 is disposed between the back contact layer 510 and the glass layer 600. The back contact layer 510 is made of a metal material, a transparent conductive oxide film or a combination of the metal material and the transparent conductive oxide film. The low reflective layer 520 is made of carbon black or conductive carbon black or carbon nanotube or carbon fiber or graphite or a combination thereof. The visible light reflectance of the third lower connecting surface 504b is less than 50%. Accordingly, the solar power sunroof device 100 having the low reflectance of the present disclosure can reduce reflection of the visible ray 120 by adding organic substances having high absorption coefficients, thus significantly minimizing mirror image and reflection phenomena to increase eye comfort and solving a problem of high reflectance in a conventional technology.

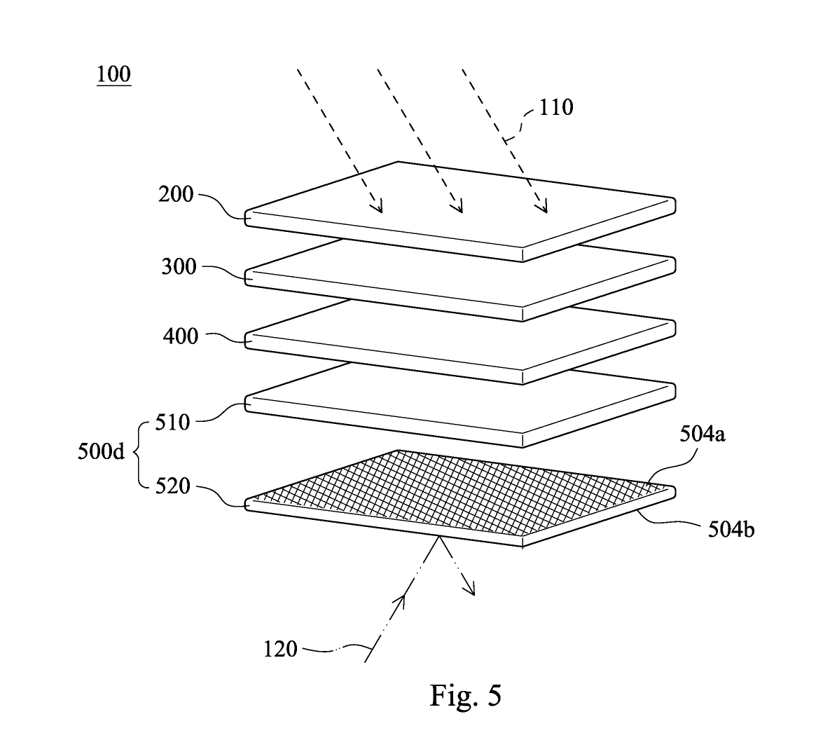

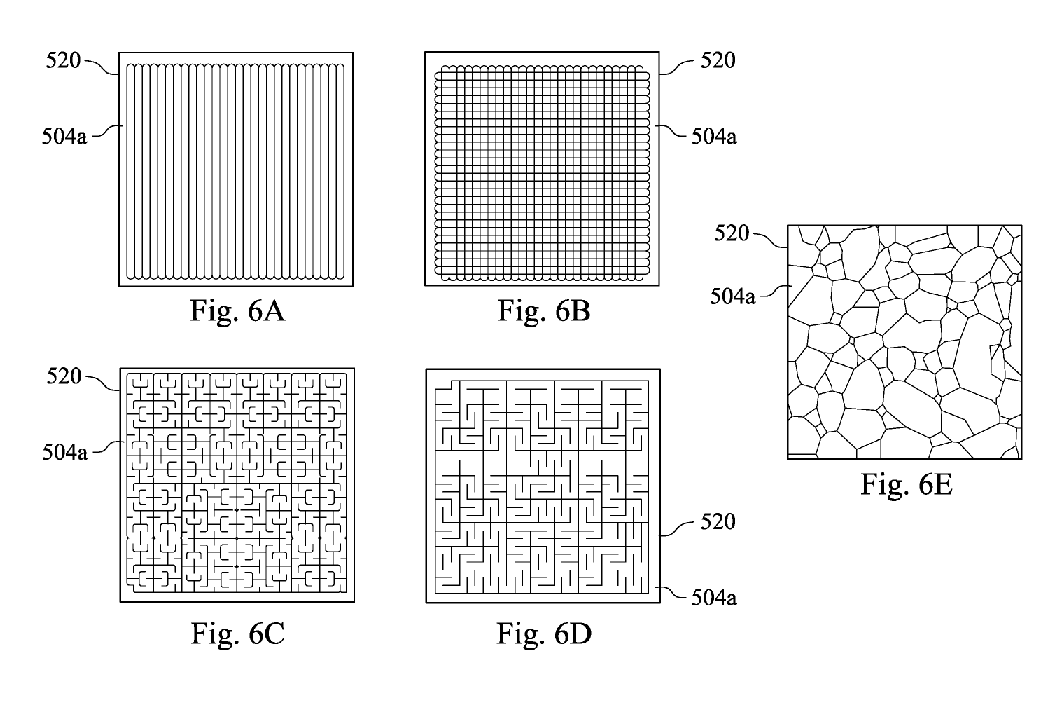

FIG. 5 shows a schematic view of a solar power sunroof device 100 having a low reflectance according to a fourth embodiment of the present disclosure; FIG. 6A shows a schematic view of the low reflective layer 520 according to a first example of FIG. 5; FIG. 6B shows a schematic view of the low reflective layer 520 according to a second example of FIG. 5; FIG. 6C shows a schematic view of the low reflective layer 520 according to a third example of FIG. 5; FIG. 6D shows a schematic view of the low reflective layer 520 according to a fourth example of FIG. 5; and FIG. 6E shows a schematic view of the low reflective layer 520 according to a fifth example of FIG. 5. In FIGS. 5 and 6A-6E, the solar power sunroof device 100 having the low reflectance is configured to utilize a metal mesh structure having a regular or irregular shape to reduce the reflectance of a back contact layer 510 made of a transparent conductive oxide film. The solar power sunroof device 100 having the low reflectance includes a substrate 200, a front contact layer 300, a photoelectric conversion layer 400 and a back contact module 500d.

In FIG. 5, the detail of the substrate 200, the front contact layer 300 and the photoelectric conversion layer 400 is the same as the first embodiment of FIG. 2 and will not be described again herein. In FIG. 5, the solar power sunroof device 100 having the low reflectance further includes the back contact module 500d. The back contact module 500d includes the back contact layer 510 and the low reflective layer 520. The back contact layer 510 is made of the transparent conductive oxide film. The low reflective layer 520 has a metal mesh structure which may be made of silver. The metal mesh structure has a line width which is greater than or equal to 10 um and is less than or equal to 500 um. The visible light reflectance of a third lower connecting surface 504b of the low reflective layer 520 is less than 50%. In FIG. 6A, the metal mesh structure is arranged in a regular pattern with parallel columns (i.e., arranged in a vertical direction). In FIG. 6B, the metal mesh structure is arranged in a regular pattern with vertically staggered arrangements. In FIGS. 6C and 6D, the metal mesh structures are arranged in a regular pattern with specific arrangements. In FIG. 6E, the metal mesh structure is arranged in an irregular pattern with large and small holes. Regardless of the shape of the metal mesh structure, the solar power sunroof device 100 having the low reflectance of the present disclosure can reduce reflection of the visible ray 120 so as to increase eye comfort.

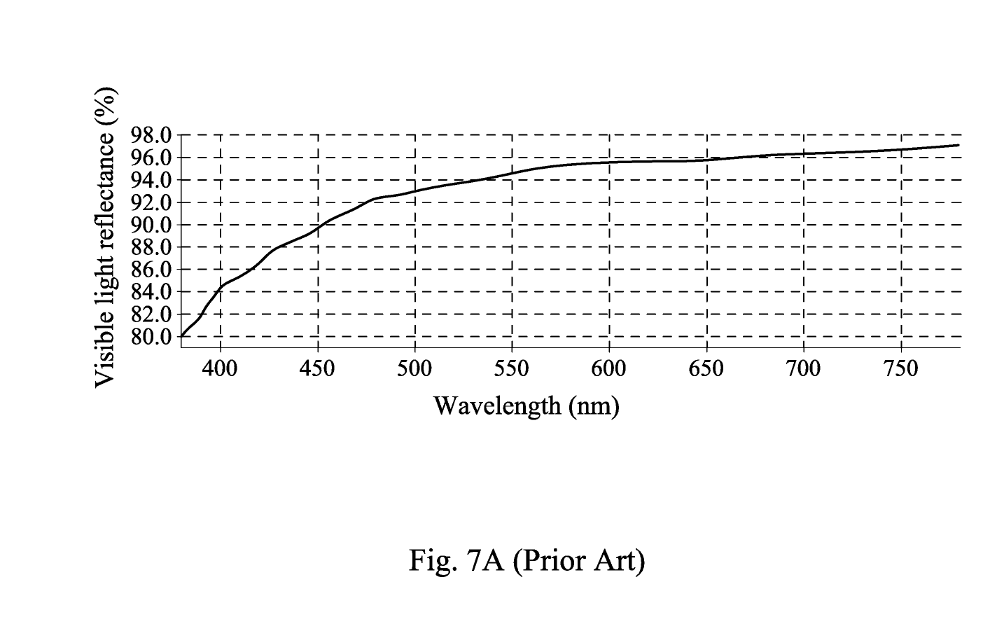

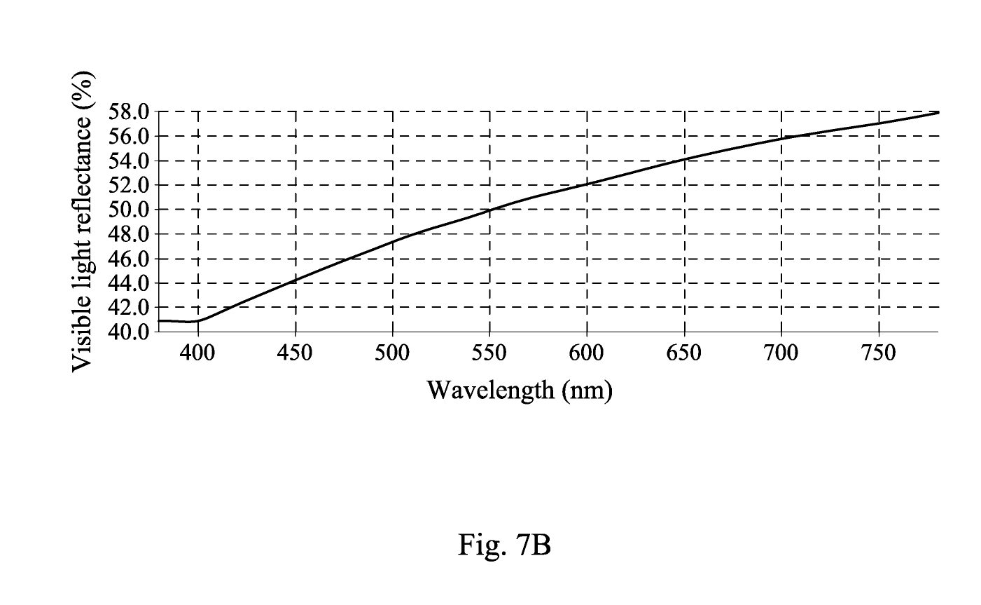

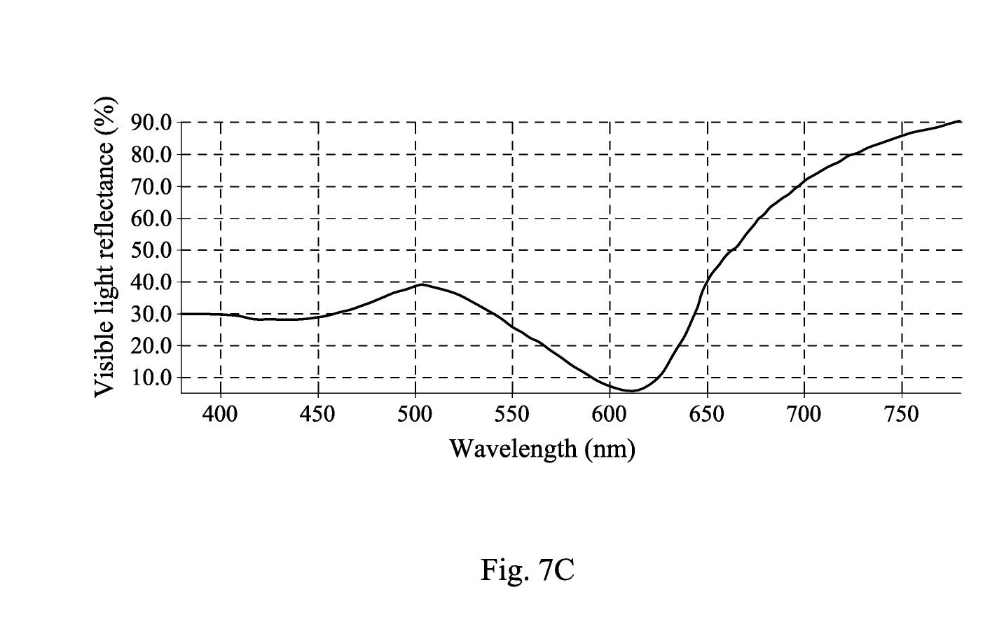

FIG. 7A shows a schematic view of a measurement result of a conventional solar power sunroof device; FIG. 7B shows a schematic view of a measurement result of the solar power sunroof device 100 having the low reflectance of FIG. 2, wherein the low reflective layer 520 is made of nickel (Ni), and FIG. 7C shows a schematic view of a measurement result of the solar power sunroof device 100 having the low reflectance of FIG. 2, wherein the low reflective layer 520 is made of amorphous silicon (a-Si). When the thickness of the back contact layer made of silver is 150 nm, and the wavelength of the visible ray is 550 nm, the visible light reflectance of the back contact layer is 94.5% in a conventional solar power sunroof device, as shown in FIG. 7A. In one embodiment of the solar power sunroof device 100 having the low reflectance of the present disclosure, when the low reflective layer 520 is made of nickel (Ni), the thickness of nickel is 100 nm, the thickness of the back contact layer 510 is 150 nm, and the wavelength of the visible ray is 550 nm, the visible light reflectance of third lower connecting surface 504b of the low reflective layer 520 is 49.9%, as shown in FIG. 7B. In another embodiment of the solar power sunroof device 100 having the low reflectance of the present disclosure, when the low reflective layer 520 is made of amorphous silicon (a-Si), the thickness of amorphous silicon is 100 nm, the thickness of the back contact layer 510 is 150 nm, and the wavelength of the visible ray is 550 nm, the visible light reflectance of third lower connecting surface 504b of the low reflective layer 520 is 25.3%, as shown in FIG. 7C. Therefore, the solar power sunroof device 100 having the low reflectance of the present disclosure can reduce the visible light reflectance via the specific structure of the back contact module 500a so as to solve a problem of high visible light reflectance of the back contact layer in the conventional solar power sunroof device.

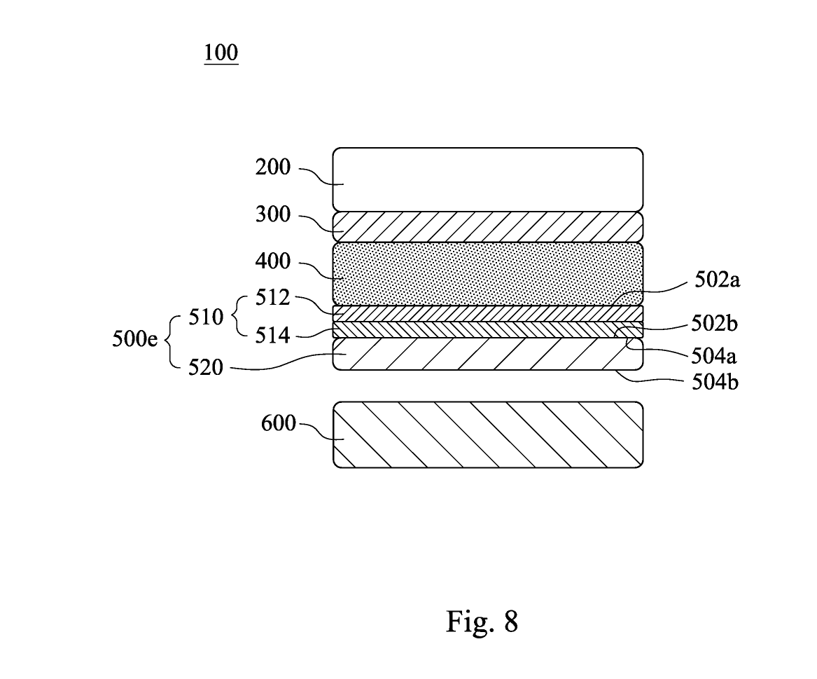

FIG. 8 shows a schematic view of a solar power sunroof device 100 having a low reflectance according to a fifth embodiment of the present disclosure. In FIGS. 1 and 8, the solar power sunroof device 100 having the low reflectance includes a substrate 200, a front contact layer 300, a photoelectric conversion layer 400, a back contact module 500e and a glass layer 600.

In FIG. 8, the detail of the substrate 200, the front contact layer 300, the photoelectric conversion layer 400 and the glass layer 600 is the same as the first embodiment of FIG. 2 and will not be described again herein. In FIG. 8, the solar power sunroof device 100 having the low reflectance further includes the back contact module 500e. The back contact module 500e includes the back contact layer 510 and the low reflective layer 520. The back contact layer 510 can be made of a metal material or a combination of the metal material and a transparent conductive oxide film. In FIG. 8, the back contact layer 510 is made of the combination of the metal material and the transparent conductive oxide film. The back contact layer 510 includes a transparent conductive oxide layer 512 and a metal contact layer 514. The metal contact layer 514 is disposed between the transparent conductive oxide layer 512 and the low reflective layer 520. The low reflective layer 520 is made of the transparent conductive oxide film so as to be transparent. Accordingly, the solar power sunroof device 100 having the low reflectance of the present disclosure can reduce the reflectance of the back contact layer 510 via the low reflective layer 520 with light absorption and low resistance, thereby significantly minimizing mirror image and reflection phenomena to increase eye comfort. Moreover, the variations in the thickness of the low reflective layer 520 can change a first color of the surface (e.g., the third lower connecting surface 504b). The vehicle body includes an interior decorative element having a second color, and the first color of the low reflective layer 520 is corresponding to the second color of the interior decorative element of the vehicle body, so that a vehicle interior of the vehicle body has a uniform color for achieving good visual effects.

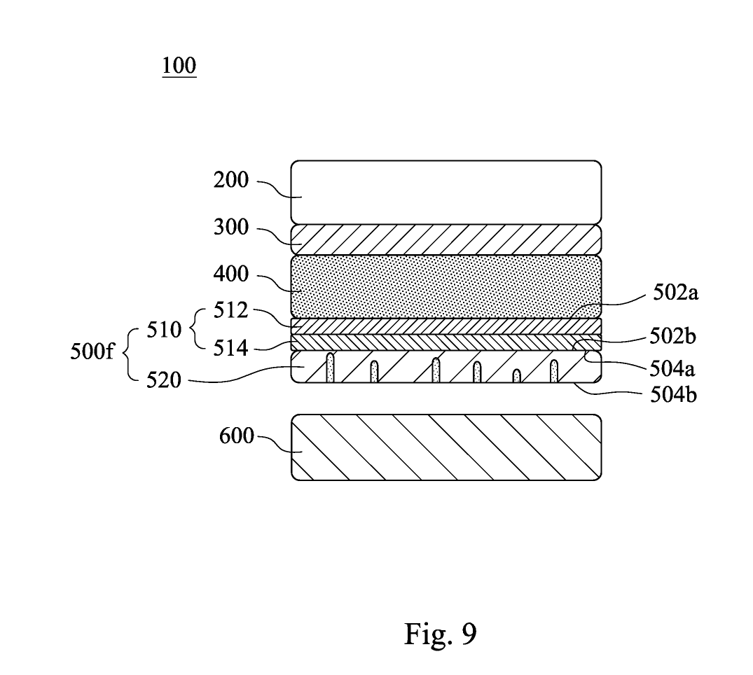

FIG. 9 shows a schematic view of a solar power sunroof device 100 having a low reflectance according to a sixth embodiment of the present disclosure. In FIGS. 1 and 9, the solar power sunroof device 100 having the low reflectance includes a substrate 200, a front contact layer 300, a photoelectric conversion layer 400, a back contact module 500f and a glass layer 600.

In FIG. 9, the detail of the substrate 200, the front contact layer 300, the photoelectric conversion layer 400 and the glass layer 600 is the same as the first embodiment of FIG. 2 and will not be described again herein. In FIG. 9, the solar power sunroof device 100 having the low reflectance further includes the back contact module 500f. The back contact module 500f includes the back contact layer 510 and the low reflective layer 520. The back contact layer 510 can be made of a metal material or a combination of the metal material and a transparent conductive oxide film. In FIG. 9, the back contact layer 510 includes a transparent conductive oxide layer 512 and a metal contact layer 514. The metal contact layer 514 is disposed between the transparent conductive oxide layer 512 and the low reflective layer 520. The low reflective layer 520 is scored by a laser beam to form a specific pattern. In other words, the third lower connecting surface 504b of the low reflective layer 520 has a pattern formed by an optical device so as to increase the surface roughness of the low reflective layer 520. Hence, the solar power sunroof device 100 having the low reflectance of the present disclosure can reduce reflection of the visible ray 120, thereby significantly minimizing mirror image and reflection phenomena to increase eye comfort.

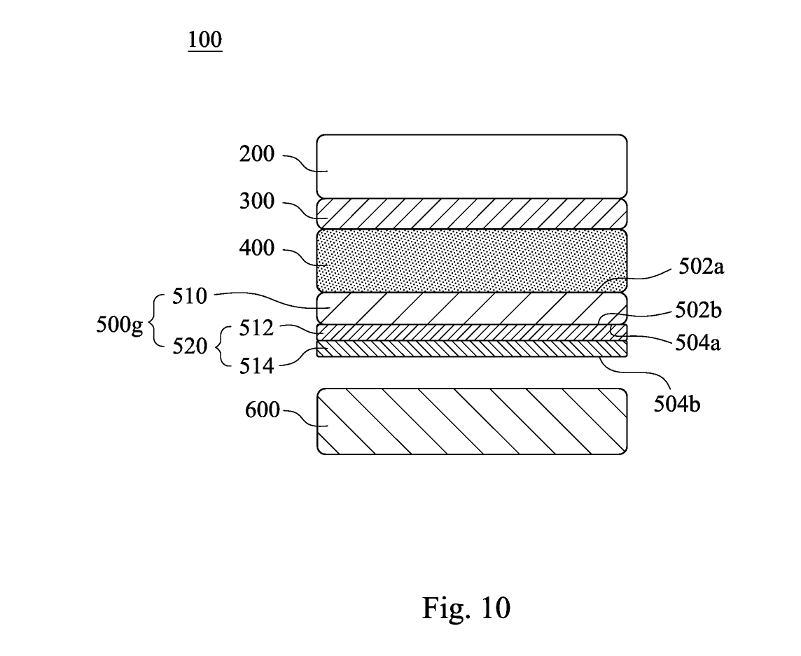

FIG. 10 shows a schematic view of a solar power sunroof device 100 having a low reflectance according to a seventh embodiment of the present disclosure. In FIGS. 1 and 10, the solar power sunroof device 100 having the low reflectance includes a substrate 200, a front contact layer 300, a photoelectric conversion layer 400, a back contact module 500g and a glass layer 600.

In FIG. 10, the detail of the substrate 200, the front contact layer 300, the photoelectric conversion layer 400 and the glass layer 600 is the same as the first embodiment of FIG. 2 and will not be described again herein. In FIG. 10, the solar power sunroof device 100 having the low reflectance further includes the back contact module 500g. The back contact module 500g includes the back contact layer 510 and the low reflective layer 520. The back contact layer 510 can be made of a metal material or a combination of the metal material and a transparent conductive oxide film. In FIG. 10, the back contact layer 510 is made of the combination of the metal material and the transparent conductive oxide film. The low reflective layer 520 includes a transparent conductive oxide layer 512 and a metal contact layer 514. The transparent conductive oxide layer 512 is disposed between the metal contact layer 514 and the back contact layer 510. The transparent conductive oxide layer 512 is connected to the back contact layer 510. A third upper connecting surface 504a is located on the transparent conductive oxide layer 512. In addition, the metal contact layer 514 is connected to the transparent conductive oxide layer 512. A third lower connecting surface 504b is located on the metal contact layer 514. The metal contact layer 514 has a metal thickness, and the metal thickness is less than 20 nm. Therefore, the variations in the thickness of the metal contact layer 514 of the low reflective layer 520 can change a first color of the surface (e.g., the third lower connecting surface 504b). The vehicle body includes an interior decorative element having a second color, and the first color of the low reflective layer 520 is corresponding to the second color of the interior decorative element of the vehicle body, so that a vehicle interior of the vehicle body has a uniform color for achieving good visual effects.

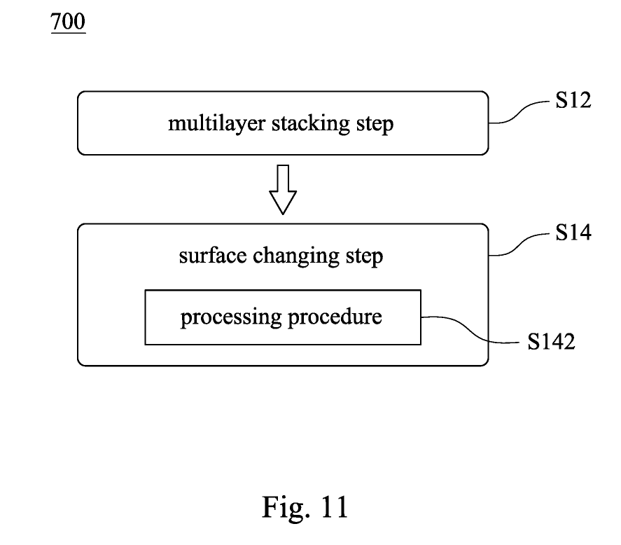

FIG. 11 shows a flow chart of a manufacturing method 700 of a solar power sunroof device 100 having a low reflectance according to one embodiment of the present disclosure. The manufacturing method 700 of the solar power sunroof device 100 having the low reflectance provides a multilayer stacking step S12 and a surface changing step S14.

The multilayer stacking step S12 is for sequentially stacking the substrate 200, the front contact layer 300, the photoelectric conversion layer 400, each of the back contact modules 500a, 500b, 500c, 500d, 500e, 500f, 500g and the glass layer 600 in FIGS. 2-5 and 8-10. The surface changing step S14 is for performing a processing procedure S142 to change the third lower connecting surface 504b so as to decrease the visible light reflectance of the third lower connecting surface 504b. In detail, in order to achieve the low reflective performance of the third lower connecting surface 504b, the visible light reflectance must be less than 50%. The manufacturing method 700 of the solar power sunroof device 100 having the low reflectance utilizes seven different processing procedures S142 to produce the back contact modules 500a, 500b, 500c, 500d, 500e, 500f, 500g having the visible light reflectance less than 50%. The seven processing procedures S142 can be more fully understood by reading the following detailed description of the embodiment.

In FIGS. 2 and 11, the processing procedure S142 of the manufacturing method 700 of the solar power sunroof device 100 having the low reflectance is for selecting the back contact layer 510 made of a metal material, a transparent conductive oxide film or a combination of the metal material and the transparent conductive oxide film, and selecting the low reflective layer 520 made of germanium (Ge), nickel (Ni), silicon (Si) or amorphous silicon (a-Si), and then correspondingly connecting the low reflective layer 520 to the back contact layer 510 to form the back contact module 500a. Therefore, the processing procedure S142 of the manufacturing method 700 of the present disclosure uses the semiconductor material having the high absorption coefficient to form the solar power sunroof device 100 having the low reflectance, thereby effectively absorbing the visible ray 120. In addition, the low reflective layer 520 of the solar power sunroof device 100 having the low reflectance has a first color after the processing procedure S142. The vehicle body includes an interior decorative element having a second color, and the first color of the low reflective layer 520 is corresponding to the second color of the interior decorative element of the vehicle body, so that a vehicle interior of the vehicle body has a uniform color for achieving good visual effects.

In FIGS. 3 and 11, the processing procedure S142 of the manufacturing method 700 of the solar power sunroof device 100 having the low reflectance is for performing an etching process to form the low reflective layer. The third lower connecting surface 504b of the low reflective layer 520 of the back contact module 500b is formed into a concave-convex shape or a sawtooth shape. The third lower connecting surface 504b has a surface roughness which is greater than or equal to 50 nm. The etching process may be a dry etching process or a wet etching process. The surface roughness can be increased by the etching process of the processing procedure S142.

In FIGS. 4 and 11, the processing procedure S142 of the manufacturing method 700 of the solar power sunroof device 100 having the low reflectance is for selecting the back contact layer 510 made of a metal material, a transparent conductive oxide film or a combination of the metal material and the transparent conductive oxide film. The processing procedure S142 is for selecting the low reflective layer 520 made of carbon black or conductive carbon black or carbon nanotube or carbon fiber or graphite or a combination thereof, and then correspondingly connecting the low reflective layer 520 to the back contact layer 510 to form the back contact module 500c. Accordingly, the processing procedure S142 of the manufacturing method 700 of the solar power sunroof device 100 having the low reflectance of the present disclosure can reduce reflection of the visible ray 120 by adding organic substances having high absorption coefficients, thus significantly minimizing mirror image and reflection phenomena to increase eye comfort.

In FIGS. 5 and 11, the processing procedure S142 of the manufacturing method 700 of the solar power sunroof device 100 having the low reflectance is for performing a developing technique or a printing technique to form the low reflective layer 520 having a metal mesh structure. The metal mesh structure may have a regular or irregular shape. The metal mesh structure has a line width which is greater than or equal to 10 um and is less than or equal to 500 um. Hence, the processing procedure S142 of the manufacturing method 700 of the solar power sunroof device 100 having the low reflectance of the present disclosure utilizes the metal mesh structure having the regular or irregular shape to effectively reduce reflection of the visible ray 120 and increase eye comfort.

In FIGS. 8 and 11, the processing procedure S142 of the manufacturing method 700 of the solar power sunroof device 100 having the low reflectance is for selecting the back contact layer 510 made of a metal material or a combination of the metal material and a transparent conductive oxide film. The processing procedure S142 is for selecting the low reflective layer 520 made of the transparent conductive oxide film, and then correspondingly connecting the low reflective layer 520 to the back contact layer 510 to form the back contact module 500e. Therefore, the processing procedure S142 of the manufacturing method 700 of the solar power sunroof device 100 having the low reflectance of the present disclosure can reduce the reflectance of the back contact layer 510 via the low reflective layer 520 with light absorption and low resistance, thereby significantly minimizing mirror image and reflection phenomena to increase eye comfort. Moreover, the variations in the thickness of the low reflective layer 520 can change a first color of the third lower connecting surface 504b. The vehicle body includes an interior decorative element having a second color, and the first color of the low reflective layer 520 is corresponding to the second color of the interior decorative element of the vehicle body, so that a vehicle interior of the vehicle body has a uniform color for achieving good visual effects.

In FIGS. 9 and 11, the processing procedure S142 of the manufacturing method 700 of the solar power sunroof device 100 having the low reflectance is for selecting the back contact layer 510 made of a metal material or a combination of the metal material and a transparent conductive oxide film. The processing procedure S142 is for selecting the low reflective layer 520 made of the transparent conductive oxide film, and then correspondingly connecting the low reflective layer 520 to the back contact layer 510 to form the back contact module 500f. Moreover, the processing procedure S142 is for applying an optical device (e.g., a laser beam) to score the low reflective layer 520 so as to form a pattern on the third lower connecting surface 504b. The pattern can increase the surface roughness of the low reflective layer 520 so as to reduce reflection of the visible ray 120 and significantly minimize mirror image and reflection phenomena to increase eye comfort.

In FIGS. 10 and 11, the processing procedure S142 of the manufacturing method 700 of the solar power sunroof device 100 having the low reflectance is for selecting the back contact layer 510 made of a metal material or a combination of the metal material and a transparent conductive oxide film. The processing procedure S142 is for selecting the low reflective layer 520 including a transparent conductive oxide layer 512 and a metal contact layer 514, and then correspondingly connecting the low reflective layer 520 to the back contact layer 510 to form the back contact module 500g. Accordingly, the manufacturing method 700 of the solar power sunroof device 100 having the low reflectance of the present disclosure utilizes specific processing procedures S142 to produce each of the back contact modules 500a, 500b, 500c, 500d, 500e, 500f, 500g so as to reduce reflection of the visible ray 120 and significantly minimize mirror image and reflection phenomena to increase eye comfort. In addition, the third lower connecting surface 504b of the low reflective layer 520 manufactured by the processing procedure S142 can significantly minimize mirror image and reflection phenomena, and the solar ray 110 can pass through the low reflective layer 520.

According to the aforementioned embodiments and examples, the advantages of the present disclosure are described as follows.

1. The specific structures of the back contact module of the present disclosure can reduce reflection of the visible ray to significantly minimize mirror image and reflection phenomena so as to increase eye comfort from the view of people inside the vehicle.

2. The solar power sunroof device having the low reflectance of the present disclosure can achieve energy generation. Moreover, an external color of the solar power sunroof device having the low reflectance is similar to the vehicle body so as to achieve good visual effects.

3. In the solar power sunroof device having the low reflectance of the present disclosure, the first color of the low reflective layer is corresponding to the second color of the interior decorative element of the vehicle body, so that a vehicle interior of the vehicle body has a uniform color for achieving good visual effects.

4. The third lower connecting surface of the low reflective layer manufactured by the processing procedure of the present disclosure can significantly minimize mirror image and reflection phenomena, and the solar ray can smoothly pass through the low reflective layer.

5. In the solar power sunroof device having the low reflectance of the present disclosure, the variations in the thickness of the low reflective layer made of the transparent conductive oxide film can change the first color of the surface. The first color of the low reflective layer is corresponding to the second color of the interior decorative element of the vehicle body, so that the vehicle interior of the vehicle body has the uniform color for achieving good visual effects.

6. The third lower connecting surface of the low reflective layer of the present disclosure has a pattern formed by an optical device so as to increase the surface roughness of the low reflective layer. Hence, the solar power sunroof device having the low reflectance of the present disclosure can reduce reflection of the visible ray and significantly minimize mirror image and reflection phenomena so as to increase eye comfort.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A solar power sunroof device having a low reflectance, which is configured to receive and reflect a solar ray and a visible ray, the solar power sunroof device having the low reflectance comprising:
a substrate illuminated by the solar ray;
a front contact layer having a first upper connecting surface and a first lower connecting surface, wherein the first upper connecting surface is connected to the substrate;
a photoelectric conversion layer connected to the first lower connecting surface;
a back contact layer having a second upper connecting surface and a second lower connecting surface, wherein the second upper connecting surface is connected to the photoelectric conversion layer; and
a low reflective layer having a third upper connecting surface and a third lower connecting surface, wherein the third upper connecting surface is connected to the second lower connecting surface, and the third lower connecting surface has a visible light reflectance;
wherein the visible ray illuminates the third lower connecting surface of the low reflective layer, and the third lower connecting surface scatters or absorbs the visible ray so as to decrease the visible light reflectance.

2. The solar power sunroof device having the low reflectance of claim 1, wherein the back contact layer is made of a metal material, a transparent conductive oxide film or a combination of the metal material and the transparent conductive oxide film, the low reflective layer is made of germanium (Ge), nickel (Ni), silicon (Si) or amorphous silicon (a-Si), and the visible light reflectance is less than 50%.

3. The solar power sunroof device having the low reflectance of claim 1, wherein the low reflective layer has a first color, the solar power sunroof device having the low reflectance is disposed on a vehicle body, the vehicle body comprises an interior decorative element having a second color, and the first color is corresponding to the second color.

4. The solar power sunroof device having the low reflectance of claim 1, wherein the back contact layer is made of a transparent conductive oxide film, the low reflective layer has a metal mesh structure, the metal mesh structure has a line width which is greater than or equal to 10 um and is less than or equal to 500 um, and the visible light reflectance is less than 50%.

5. The solar power sunroof device having the low reflectance of claim 1, wherein the low reflective layer is made of a metal material or a transparent conductive oxide film, the third lower connecting surface has a concave-convex shape or a sawtooth shape, the third lower connecting surface has a surface roughness which is greater than or equal to 50 nm, and the visible light reflectance is less than 50%.

6. The solar power sunroof device having the low reflectance of claim 1, wherein the back contact layer is made of a metal material, a transparent conductive oxide film or a combination of the metal material and the transparent conductive oxide film, the low reflective layer is made of carbon black or conductive carbon black or carbon nanotube or carbon fiber or graphite or a combination thereof, and the visible light reflectance is less than 50%.

7. The solar power sunroof device having the low reflectance of claim 1, wherein the back contact layer is made of a metal material or a combination of the metal material and a transparent conductive oxide film, the low reflective layer is made of the transparent conductive oxide film so as to be transparent.

8. The solar power sunroof device having the low reflectance of claim 7, wherein the third lower connecting surface of the low reflective layer has a pattern formed by an optical device.

9. The solar power sunroof device having the low reflectance of claim 1, wherein the back contact layer is made of a metal material or a combination of the metal material and a transparent conductive oxide film, and the low reflective layer comprises:
a transparent conductive oxide layer connected to the back contact layer, wherein the third upper connecting surface is located on the transparent conductive oxide layer; and
a metal contact layer connected to the transparent conductive oxide layer, wherein the third lower connecting surface is located on the metal contact layer, the metal contact layer has a metal thickness, and the metal thickness is less than 20 nm.

10. A manufacturing method of the solar power sunroof device having the low reflectance of claim 1, comprising:
providing a multilayer stacking step, wherein the multilayer stacking step is for sequentially stacking the substrate, the front contact layer, the photoelectric conversion layer, the back contact layer and the low reflective layer; and
providing a surface changing step, wherein the surface changing step is for performing a processing procedure to change the third lower connecting surface so as to decrease the visible light reflectance of the third lower connecting surface.

11. The manufacturing method of claim 10, wherein the processing procedure is for selecting the back contact layer made of a metal material, a transparent conductive oxide film or a combination of the metal material and the transparent conductive oxide film, and selecting the low reflective layer made of germanium (Ge), nickel (Ni), silicon (Si) or amorphous silicon (a-Si), and then correspondingly connecting the low reflective layer to the back contact layer.

12. The manufacturing method of claim 11, wherein the solar power sunroof device having the low reflectance is disposed on a vehicle body, and the vehicle body comprises an interior decorative element having a second color;
wherein after performing the processing procedure, the solar power sunroof device having the low reflectance has a first color, and the first color is corresponding to the second color.

13. The manufacturing method of claim 10, wherein the processing procedure is for performing a developing technique or a printing technique to form the low reflective layer having a metal mesh structure, and the metal mesh structure has a line width which is greater than or equal to 10 um and is less than or equal to 500 um.

14. The manufacturing method of claim 10, wherein the processing procedure is for performing an etching process to form the low reflective layer, the third lower connecting surface of the low reflective layer is formed into a concave-convex shape or a sawtooth shape, and the third lower connecting surface has a surface roughness which is greater than or equal to 50 nm.

15. The manufacturing method of claim 10, wherein the processing procedure is for selecting the back contact layer made of a metal material, a transparent conductive oxide film or a combination of the metal material and the transparent conductive oxide film, and selecting the low reflective layer made of carbon black or conductive carbon black or carbon nanotube or carbon fiber or graphite or a combination thereof, and then correspondingly connecting the low reflective layer to the back contact layer.

16. The manufacturing method of claim 10, wherein the processing procedure is for selecting the back contact layer made of a metal material or a combination of the metal material and a transparent conductive oxide film, and selecting the low reflective layer made of the transparent conductive oxide film, and then correspondingly connecting the low reflective layer to the back contact layer.

17. The manufacturing method of claim 16, wherein the processing procedure is for applying an optical device to score the low reflective layer so as to form a pattern on the third lower connecting surface.

18. The manufacturing method of claim 10, wherein the processing procedure is for selecting the back contact layer made of a metal material or a combination of the metal material and a transparent conductive oxide film, and selecting the low reflective layer comprising a transparent conductive oxide layer and a metal contact layer, and then correspondingly connecting the low reflective layer to the back contact layer.
